(19) United States
(12) Patent Application Publication
(10) Pub. No.: US 2026/0255598 A1
(43) Pub. Date: Aug. 27, 2026

(54) MANAGING ISOLATION STRUCTURES IN THREE-DIMENSIONAL SEMICONDUCTOR DEVICES

(71) Applicant: Yangtze Memory Technologies Co., Ltd., Wuhan (CN)

(72) Inventors: Xiaojing GU, Wuhan (CN); Wei YUAN, Wuhan (CN); Huiwen LIU, Wuhan (CN); Yuhui HAN, Wuhan (CN); Di WANG, Wuhan (CN)

(21) Appl. No.: 19/176,121

(22) Filed: Apr. 10, 2025

(30) Foreign Application Priority Data
Feb. 26, 2025 (CN) 202510220481.5

(51) Int. Cl. H10B 43/27; H10B 43/10

(52) U.S. Cl. CPC H10B 43/27; H10B 43/10

(57) ABSTRACT

Systems, devices, and methods for managing isolation structures in a semiconductor device are provided. In one aspect, a semiconductor device includes a stack of conductive layers and insulating layers; a gate line slit structure including a first segment and a second segment each having first curved portions, where the first curved portions of the first segment includes an end portion and a second portion in contact with the end portion; and an isolation structure separating the first segment from the second segment. The isolation structure includes second curved portions, and an end portion of second curved portions is in contact with the end portion of the first segment. The end portion of the first segment includes a first curved surface, the second portion includes a second curved surface, and an arc length of the first curved surface is greater than an arc length of the second curved surface.

### CROSS-REFERENCE TO RELATED APPLICATIONS

This application claims priority to Chinese Patent Application No. 202510220481.5, filed on February 26, 2025, which is hereby incorporated by reference in its entirety.

### TECHNICAL FIELD

The present disclosure relates to semiconductor devices and fabrication processes for semiconductor devices.

### BACKGROUND

Semiconductor devices may be classified into non-volatile memory devices, such as flash memory devices, NAND memory device, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for managing isolation structures in three-dimensional (3D) semiconductor devices.

One aspect of the present disclosure features a semiconductor device, including a stack of conductive layers and insulating layers alternating with each other along a first direction; a gate line slit structure extending in the stack and including at least a first segment and a second segment each having a plurality of first curved portions arranged in a line along a second direction different from the first direction, where the plurality of first curved portions of the first segment includes an end portion and a second portion in contact with the end portion; and an isolation structure extending in the stack and separating the first segment from the second segment in the line along the second direction. The isolation structure includes a plurality of second curved portions arranged in the line along the second direction, and an end portion of the plurality of second curved portions is in contact with the end portion of the plurality of first curved portions of the first segment along the second direction. The end portion of the plurality of first curved portions of the first segment includes a first curved surface in contact with the stack, the second portion of the plurality of first curved portions of the first segment includes a second curved surface in contact with the stack, and an arc length of the first curved surface in a plane perpendicular to the first direction is greater than an arc length of the second curved surface in the plane.

In some implementations, a distance between the end portion of the plurality of second curved portions and the end portion of the plurality of first curved portions of the first segment is greater than a pitch of the plurality of the first curved portions of the first segment.

In some implementations, a pitch of the plurality of second curved portions is greater than the pitch of the plurality of the first curved portions of the first segment.

In some implementations, the pitch of the plurality of the first curved portions of the first segment is a distance between centroids of two adjacent first curved portions, and the distance between the end portion of the plurality of second curved portions and the end portion of the plurality of first curved portions of the first segment is a distance between a centroid of the end portion of the plurality of second curved portions and a centroid of the end portion of the plurality of first curved portions of the first segment.

In some implementations, the end portion of the plurality of second curved portions includes a concave surface, and the end portion of the plurality of first curved portions of the first segment includes a convex surface in contact with the concave surface.

In some implementations, the isolation structure includes a first sidewall in contact with the first segment and a second sidewall in contact with the second segment. The first sidewall and the second sidewall each has a concave surface extending inwardly along the second direction. The isolation structure further includes a third sidewall and a fourth sidewall both in contact with the stack along a third direction different from the first direction and the second direction, and the third sidewall and the fourth sidewall each include a series of curved surfaces including the first curved surface and the second curved surface.

In some implementations, the semiconductor device includes a plurality of channel structures extending along the first direction. A part of the stack is between the isolation structure and the plurality of channel structures along a third direction different from the first direction and the second direction.

In some implementations, a bottom of the isolation structure includes one or more protrusions extending outward along the first direction and is arranged in the line along the second direction.

In some implementations, the first segment is in an array region, the second segment and the isolation structure are in a connection region adjacent to the array region along the second direction.

In some implementations, the first segment, the second segment, and the isolation structure are in an array region.

Another aspect of the present disclosure features a method including: providing a semiconductor structure including a stack of sacrificial layers and insulating layers alternating with each other along a first direction; forming gate line slit holes arranged in a line along a second direction different from the first direction, where the gate line slit holes include a first group of gate line slit holes, a second group of gate line slit holes and a third group of gate line slit holes, the first group of gate line slit holes is between the second group of gate line slit holes and the third group of gate line slit holes, an end hole of the first group of gate line slit holes is adjacent to an end hole of the second group of gate line slit holes, and a distance between the end hole of the first group of gate line slit holes and the end hole of the second group of gate line slit holes is greater than a pitch of the second group of gate line slit holes; forming an isolation trench by expanding the first group of gate line slit holes; and forming an isolation structure by filling a dielectric material into the isolation trench.

In some implementations, a pitch of the first group of gate line slit holes is greater than the pitch of the second group of gate line slit holes.

In some implementations, a pitch of the second group of gate line slit holes is equal to a pitch of the third group of gate line slit holes.

In some implementations, the isolation trench includes expanded gate line slit holes formed from the first group of gate line slit holes, and the expanded gate line slit holes from the first group of gate line slit holes are connected with each other along the second direction.

In some implementations, the method includes filling the gate line slit holes with a first filler; removing the first filler in the second group of gate line slit holes and the third group of gate line slit holes; forming a first segment of a gate line slit trench and a second segment of the gate line slit trench by expanding the second group of gate line slit holes and the third group of gate line slit holes, respectively, where the expanded gate line slit holes from the second group of gate line slit holes are connected with each other along the second direction, and the expanded gate line slit holes from the third group of gate line slit holes are connected with each other along the second direction; and depositing a second filler in the gate line slit trench.

In some implementations, the first segment of the gate line slit trench and the second segment of the gate line slit trench are separated from the first group of gate line slit holes that is filled with the first filler by a part of the stack.

In some implementations, the gate line slit trench and the isolation trench are connected.

In some implementations, the isolation trench is formed after depositing the second filler in the gate line slit trench.

In some implementations, forming the isolation trench includes forming a dielectric layer on the first group of gate line slit holes that are filled with the first filler; forming an opening extending through the dielectric layer to expose at least a part of the first filler in each gate line slit hole of the first group of gate line slit holes; and removing the first filler in the first group of gate line slit holes.

In some implementations, the method includes removing the sacrificial layers in a connection region of the semiconductor structure; removing the sacrificial layers in an array region of the semiconductor structure, the array region is adjacent to the connection region along the second direction; and forming conductive layers between the insulating layers in both the connection region and the array region.

In some implementations, the method includes removing the second filler in the second segment of the gate line slit trench; removing, by introducing an etchant through the second segment of the gate line slit trench, the sacrificial layers in the connection region to form second opening space; filling the second segment of the gate line slit trench and the second opening space with a third filler; removing the second filler in the first segment of the gate line slit trench; removing, by introducing the etchant through the first segment of the gate line slit trench, the sacrificial layers in the array region to form first opening space; removing the third filler in the connection region; and depositing at least a conductive material into the first opening space and the second opening space through at least one of the first segment of the gate line slit trench or the second segment of the gate line slit trench.

In some implementations, the method includes removing the second filler in the second segment of the gate line slit trench; depositing a spacer layer in the gate line slit trench; and depositing a final filler in the gate line slit trench.

In some implementations, the first segment of the gate line slit trench is in the array region of the semiconductor structure, and the isolation structure and the second segment of the gate line slit trench are in the connection region of the semiconductor structure.

Another aspect of the present disclosure features a memory system including: a memory device; and a memory controller coupled to the memory device and configured to control the memory device. The memory device includes: a stack of conductive layers and insulating layers alternating with each other along a first direction; a gate line slit structure extending in the stack and including at least a first segment and a second segment each having a plurality of first curved portions arranged in a line along a second direction different from the first direction, where the plurality of first curved portions of the first segment includes an end portion and a second portion in contact with the end portion; and an isolation structure extending in the stack and separating the first segment from the second segment in the line along the second direction. The isolation structure includes a plurality of second curved portions arranged in the line along the second direction, and an end portion of the plurality of second curved portions is in contact with the end portion of the plurality of first curved portions of the first segment along the second direction. The end portion of the plurality of first curved portions of the first segment includes a first curved surface in contact with the stack, the second portion of the plurality of first curved portions of the first segment includes a second curved surface in contact with the stack, and an arc length of the first curved surface in a plane perpendicular to the first direction is greater than an arc length of the second curved surface in the plane.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates an example three-dimensional (3D) semiconductor device.

FIG. 2A illustrates a plan view of a part of an example semiconductor device.

FIG. 2B illustrates a cross-sectional view of a part of an example semiconductor device.

FIGS. 3A-1 through FIGS. 3G-3 illustrate plan views and cross-sectional views of an example semiconductor device at various stages of a manufacture process.

FIG. 4 is a flowchart of a process of an example method to form a semiconductor device.

FIG. 5 illustrates a block diagram of an example system having one or more semiconductor devices.

Like reference numbers and designations in the various drawings indicate like elements. It is to be understood that the various exemplary implementations shown in the figures are merely illustrative representations and are not necessarily drawn to scale.

### DETAILED DESCRIPTION

As the number of layers in three-dimensional (3D) NAND increases, structures with high aspect ratio becomes more challenging to etch. Channel holes that are used for forming NAND memory cells may be etched separately for different decks. Forming channel holes and gate line slit holes together may address etching difficulties while simultaneously reducing overall costs. The process window can also be enlarged by reducing the photolithography overlay issue between the channel holes and gate line slit holes. However, as the number of layers increases, the structural stability of a stack (e.g., the stack of gate lines and isolating layers alternating with each other) may deteriorate, leading to a risk of collapse. To improve stability, an isolation structure may be inserted between adjacent segments of gate line slit structures and between adjacent two memory blocks. In some examples, isolation structures may use polysilicon as a filling material due to an erosion concern, which may increase manufacturing costs. In addition, the chemicals used during a formation of gate line slit structures may erode or oxidize filling materials in neighboring isolation structure hole due to the short distance between the gate line slit trench and the isolation structure hole. The short distance may also constrain the process window during the formation of isolation structure. Therefore, reducing manufacturing costs as well as achieving a large process window for forming the isolation structures can be challenging.

Implementations of the present disclosure provide semiconductor devices and methods to form such semiconductor devices. In some implementations, a semiconductor device includes a stack of conductive layers and insulating layers alternating with each other along a first direction; a gate line slit structure extending in the stack and including at least a first segment and a second segment each having a plurality of first curved portions arranged in a line along a second direction different from the first direction, where the plurality of first curved portions of the first segment includes an end portion and a second portion in contact with the end portion; and an isolation structure extending in the stack and separating the first segment from the second segment in the line along the second direction. The isolation structure includes a plurality of second curved portions arranged in the line along the second direction, and an end portion of the plurality of second curved portions is in contact with the end portion of the plurality of first curved portions of the first segment along the second direction. The end portion of the plurality of first curved portions of the first segment includes a first curved surface in contact with the stack, the second portion of the plurality of first curved portions of the first segment includes a second curved surface in contact with the stack, and an arc length of the first curved surface in a plane perpendicular to the first direction is greater than an arc length of the second curved surface in the plane.

Implementations of the present disclosure can provide one or more of the following technical advantages and/or benefits. First, the isolation structure can include a plurality of curved portions arranged in a line, and the gate line slit structure can also include a plurality of curved portions arranged in the line. Some curved portions can have a substantially barrel shape. An end curved portion of the isolation structure can be in contact with an end curved portion of an adjacent segment of the gate slit structure. The techniques increase a distance (e.g., inter-center distance) between the end portion of the isolation structure and the end portion of adjacent segment of the gate line slit structure. In some examples, the increased inter-center distance between the end portion of the isolation structure and the end portion of the adjacent gate line slit structure can be greater than a pitch of curved portions of the gate line slit structures. When forming the gate line slit structure, the increased distance will reduce or eliminate the risk of the filler in isolation structure holes being eroded or oxidized by chemicals used in the formation of the gate line slit structure. Therefore, without the concern of erosion, a more cost-effective sacrificial material (e.g., carbon) can be used as the filler for the isolation structure holes. In addition, the technologies described in the present disclosure can also enable a larger process window for forming the isolation structures, as the gate slit structure is further away from a center of the end curved portion of the isolation structure. Larger process windows can improve yield and provide greater process stability.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

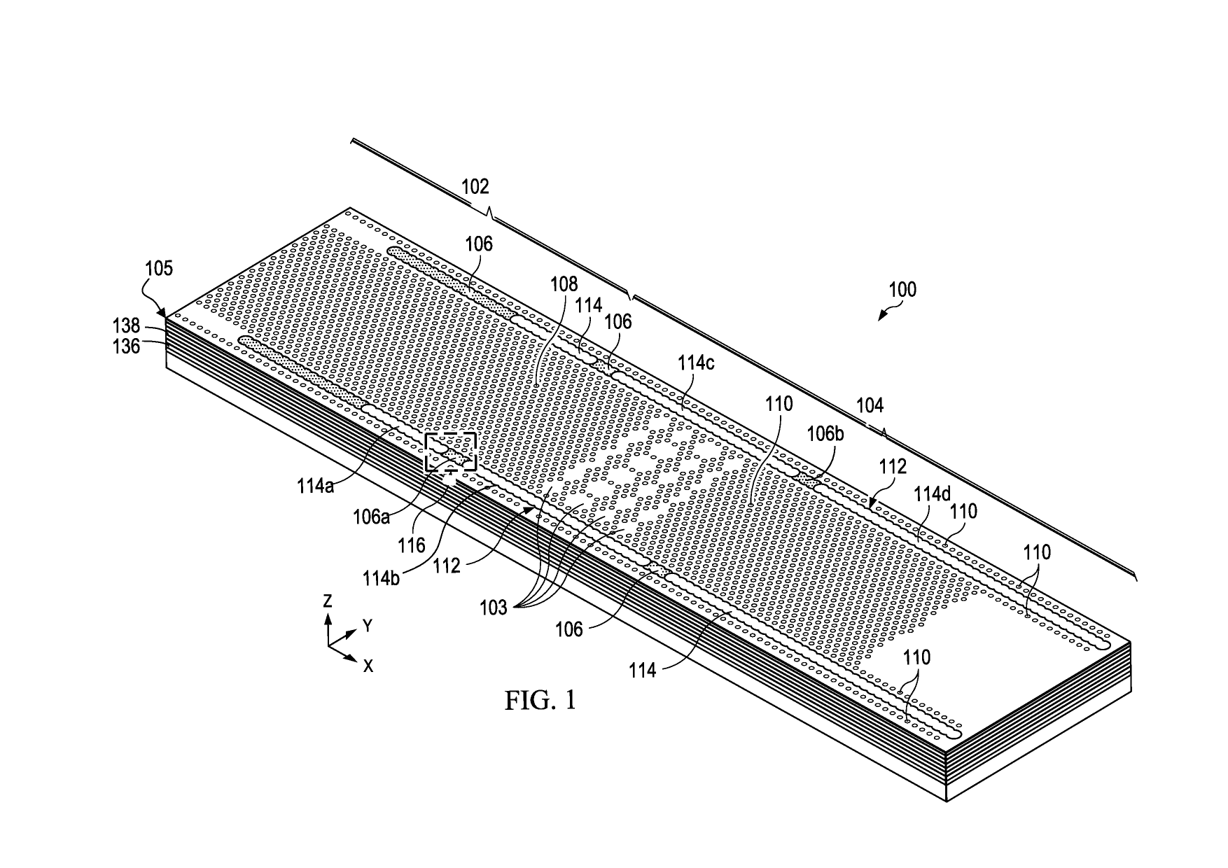

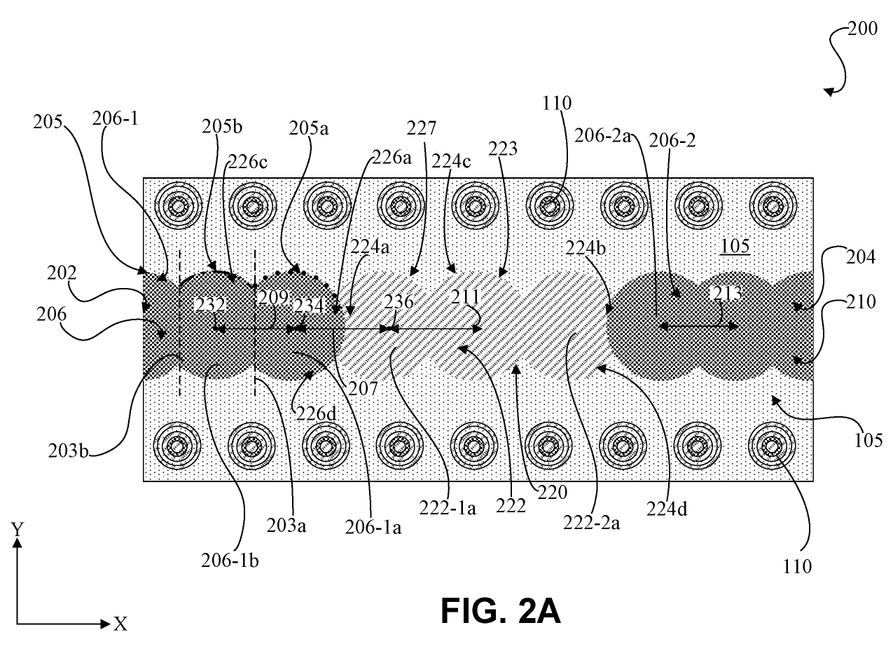

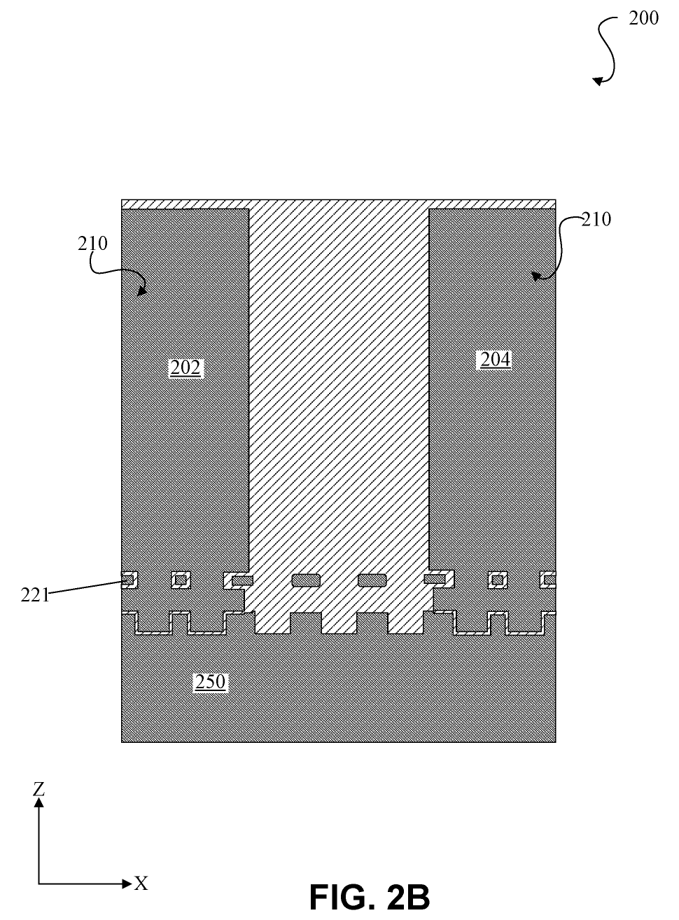

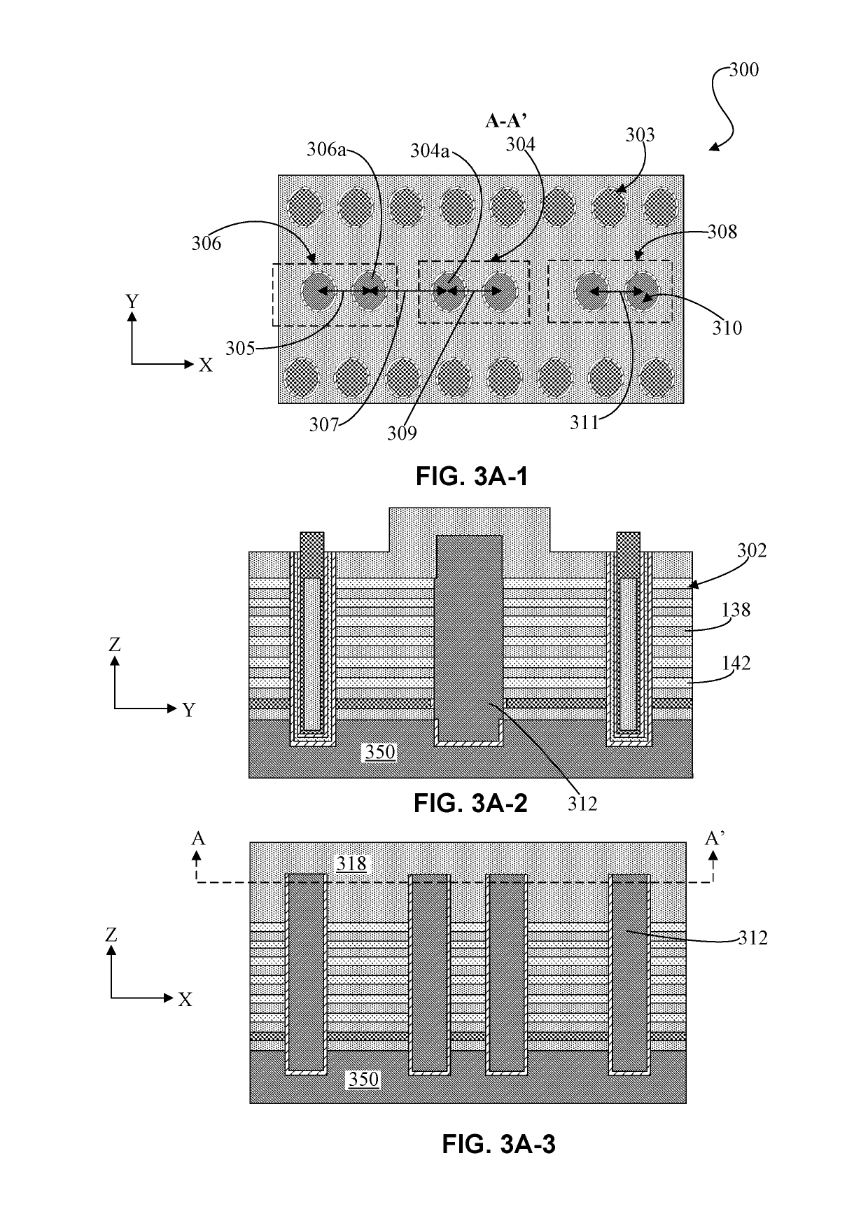

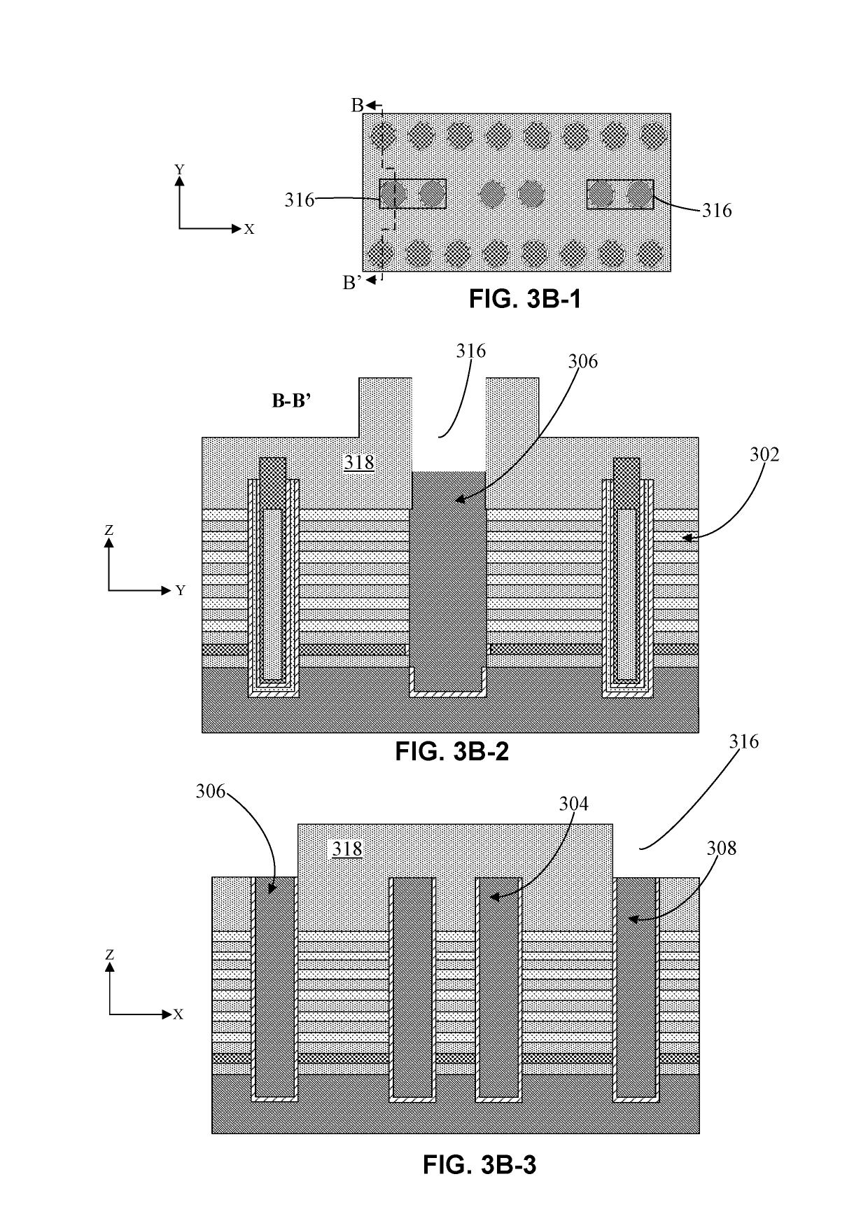

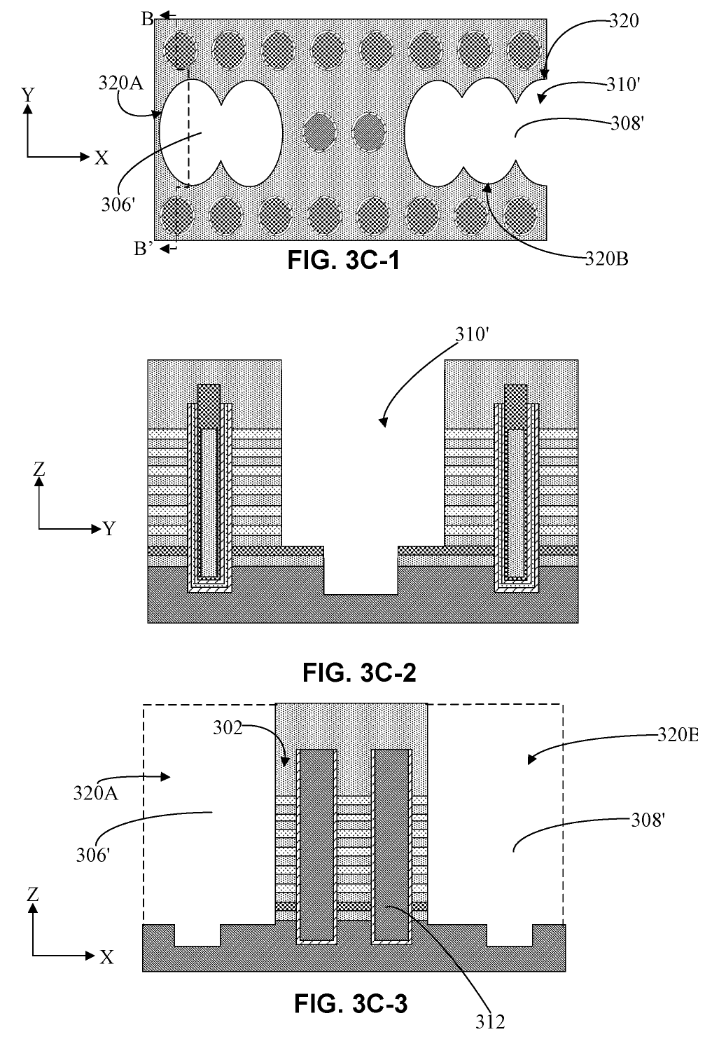

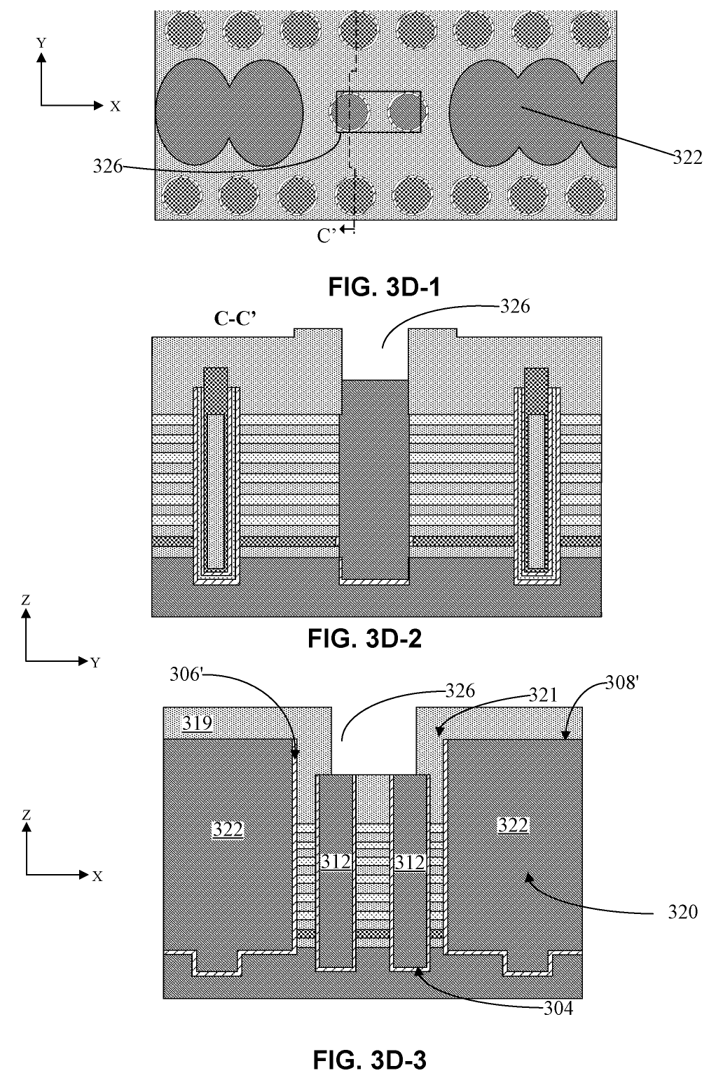

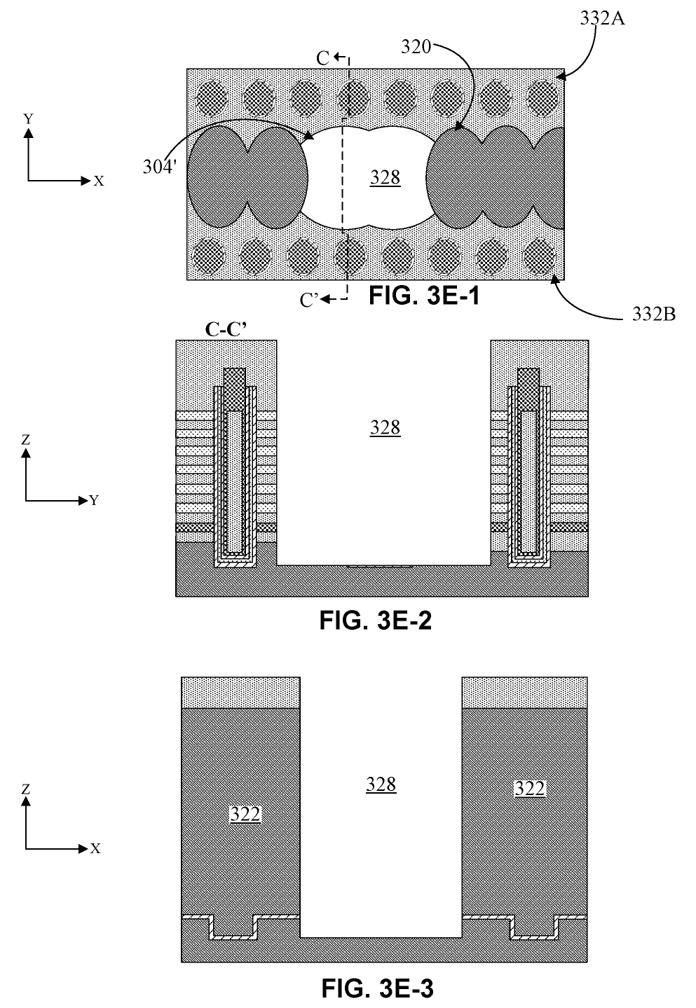

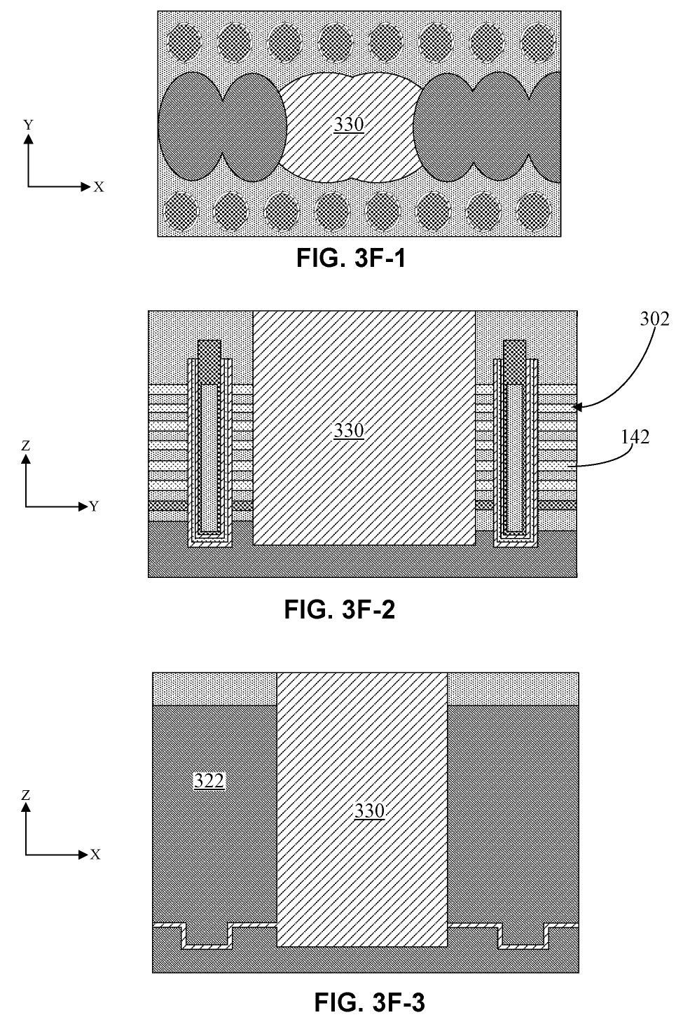

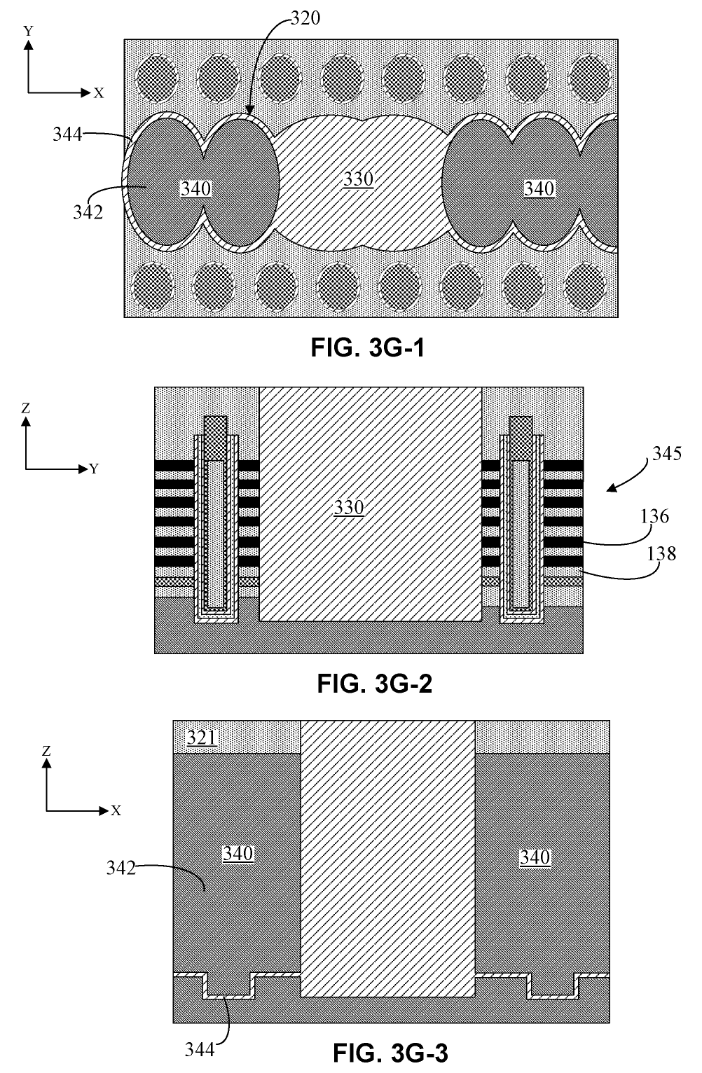

FIG. 1 illustrates a perspective view of an example semiconductor device 100. It is noted that X, Y, and Z axes (also referred to as X, Y, and Z directions) are included in FIG. 1 (and FIGS. 2A through 3G-3) to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

In some implementations, the semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1, the semiconductor device 100 includes an array region 102 and a connection region 104 adjacent to the array region 102 along a first horizontal direction (e.g., the X direction). In some implementations, an array of channel structures 108 can be in the array region 102. One or more channel structures 108 can be used to form a string of memory cells coupled in serial along a vertical direction (e.g., Z direction) perpendicular to the first horizontal direction. In some implementations, a staircase structure (not shown) and an array of contact structures (not shown) formed on the staircase structure can be in the connection region 104. In some other implementations, conductive layers in the connection region 104 can form a structure different from a staircase structure. For example, a contact structure can be connected to a corresponding conductive layer and can extend through other conductive layers, and spacer for insulation can be formed between the contact structure and the other conductive layers. In some implementations, the semiconductor device 100 can include dummy channel structures 110 (also referred to as dummy memory strings) for process variation control during fabrication and/or for additional mechanical support. In some implementations, the dummy channel structures 110 are in the connection region 104. For example, some dummy channel structures 110 can be in an edge or peripheral area of the connection region 104. In some instances, the edge area of the connection region 104 is adjacent to the array region 102. In some other instances, the edge area of the connection region 104 is adjacent to a gate line slit structure (e.g., gate line slit structure 112 as shown in FIG. 1). In some implementations, the dummy channel structures 110 are in the array region 102 (e.g., an area adjacent to the connection region 104). It is understood that the example in FIG. 1 is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along the X direction. In some other instances, the semiconductor device 100 can have two array regions 102 and a connection region 104 between the two array regions 102 along the X direction.

In some implementations, an array of sub-regions 103 can be in the connection region 104. In some instances, trough array contacts (TACs), which are not shown in FIG. 1, can be formed in the sub-regions 103. The TACs can extend through a stack 105 of alternating conductive layers 136 and insulating layers 138 and connect components on opposite sides of the stack (e.g., along the vertical direction). Dummy channel structures 110 can be located outside of the sub-regions 103 and can surround the sub-regions 103 laterally.

The semiconductor device 100 can include one or more gate line slit structures 112. Each gate line slit structure 112 can extend in the X direction. The gate line slit structure 112 can extend into both the array region 102 and the connection region 104. In some implementations, the gate line slit structures 112 can divide an array region into multiple memory blocks. In some implementations, the gate line slit structure 112 can function as a common source contact for the channel structures 108 in the array region 102. As shown in FIG. 1, each gate line slit structure 112 can include multiple segments 114 extending along the X direction. The segments 114 can be separated and spaced by isolation structures 106 along the X direction. The isolation structures 106 can eliminate or reduce stress built in the gate line slit structure 112 during the manufacturing process, thereby preventing the gate line slit structure 112 from bending or cracking. In some implementations, as shown in FIGS. 1A-1B, the isolation structure 106 is in the connection region 104 and is adjacent to the array region 102. In some other implementations, the isolation structure 106 is in the array region 102 and is adjacent to the connection region 104. In some other implementations, the isolation structure 106 can have a portion in the array region 102 and another portion in the connection region 104. In some implementations (not shown in FIG. 1), the gate line slit structure 112 can further include one or more segments 114 extending along a second horizontal direction (e.g., the Y direction). In some implementations, the gate line slit structure 112 can include multiple segments 114 connected in an H shape or a T shape.

FIG. 2A illustrates a plan view of a part of an example semiconductor device 200. FIG. 2B illustrates a cross-sectional view of a part of the example semiconductor device 200. The semiconductor device 200 can be the semiconductor device 100 of FIG. 1.

As noted above, the semiconductor device 200 can include a stack 105 of conductive layers 136 and insulating layers 138 alternating with each other along a first direction (e.g., Z direction in FIG. 1). The insulating layers 138 can include dielectric material, such as silicon oxide, silicon nitride, silicon oxynitride, or any combination thereof. In some implementations, the insulating layers 138 include silicon oxide. In some implementations, the conductive layers 136 includes a conductive material including, but not limited to W, Co, Cu, Al, TiN, TaN, polysilicon, silicide, or any combination thereof. In some implementations, each of the conductive layers 136 includes multiple conductive layers, such as a W layer over a TiN layer.

The semiconductor device 200 can further include a gate line slit structure 210 extending in the stack 105. In some implementations, the gate line slit structure 210 includes at least a first segment 202 and a second segment 204 separated from each other by an isolation structure 220. The gate line slit structure 210 can be the gate line slit structure 112 in FIG. 1. The first segment 202 and the second segment 204 can be the segment 114 of the gate line slit structure in FIG. 1. The isolation structure 220 can be the isolation structure 106 of FIG. 1.

As illustrated in FIG. 2A, in some implementations, each segment of the gate line slit structure 210 includes a plurality of first curved portions 206 arranged in a line along X direction. Each curved portion 206 can have a substantially barrel-shaped body with two narrower ends and a bulging middle. For example, the first curved portion 206-1b can be the portion between two dashed lines 203a, 203b, where its width along Y direction is narrower at both ends and wider in the middle. It is to be understood that dashed lines 203a, 203b are for illustration purpose only, and not a part of a real device. The first curved portions 206 in the first segment 202 of the gate line slit structure 210 can be denoted as 206-1, while the first curved portions 206 in the second segment 204 of the gate line slit structure 210 can be denoted as 206-2 in the present disclosure. The first curved portions 206 in both segments can have the same size (e.g., width, diameter, length and/or height along X, Y or Z directions) and pitch.

In some implementations, the plurality of first curved portions 206 of the first segment 202 includes an end portion 206-1a and a second portion 206-1b in contact with the end portion 206-1a. For example, the end portion 206-1a can be the portion between the first dashed line 203a and the isolation structure 220. The second portion 206-1b can be the portion between the two dashed lines 203a, 203b, as noted above. The end portion 206-1a can be the closest to the isolation structure 220, while the second portion 206-1b can be the second closest to the isolation structure 220.

In some implementations, the isolation structure 220 includes a plurality of second curved portions 222 arranged in the line along X-direction. The plurality of second curved portions 222 can also have a first end portion 222-1a that is in contact with the end portion 206-1a of the plurality of first curved portions 206 of the first segment 202 along X-direction, as illustrated in FIG. 2A. Additionally, the plurality of second curved portions 222 can have a second end portion 222-2a that is opposite to its first end portion 222-1a along the x direction. The second end portion 222-2a of the isolation structure 220 can be in contact with the end portion 206-2a of the plurality of first curved portions 206 of the second segment 204 along X-direction. In other words, the isolation structure 220 can be in contact with the gate line slit structure 210 on both ends.

In some implementations, the isolation structure 220 includes a first sidewall 224a in contact with the first segment 202 and a second sidewall 224b in contact with the second segment 204. As illustrated in FIG. 2A, the first sidewall 224a and the second sidewall 224b each has a concave surface extending inwardly along X-direction. The isolation structure 220 further includes a third sidewall 224c and a fourth sidewall 224d both in contact with the stack along Y direction, and the third sidewall 224c and the fourth sidewall 224d, each including a series of curved surfaces corresponding to the second curved portions 222. Each curved surface can have a convex shape, as illustrated in FIG. 2A.

In some implementations, the first segment 202 includes a first sidewall 226a in contact with the first sidewall 224a of the isolation structure 220, and a second sidewall (not shown in FIG. 2A) opposite to the first sidewall 224a along X direction and in contact with another isolation structure. As illustrated in FIG. 2A, the first sidewall 226a of the first segment 202 can have a convex surface extending outwardly towards the isolation structure 220 along X-direction. The convex surface of the first sidewall 226a of the first segment 202 can match and be in contact with the concave surface of the first sidewall 224a of the isolation structure 220. The first segment 202 further includes a third sidewall 226c and a fourth sidewall 226d both in contact with the stack 105 along Y direction. Each of the third sidewall 226c and the fourth sidewall 226d of the first segment 202 can include a series of curved surfaces 205 corresponding to the first curved portions 206 of the first segment 202. Each curved surface 205 of the first segment 202 can have a convex shape, as illustrated in FIG. 2A.

With continued reference to FIG. 2A, as the first sidewall 226a of the first and second segment 202, 204 has a convex shape extending outwardly along X direction, the end portions 206-1a, 206-2a of the first and second segment 202, 204 can have a substantially spherical shape, e.g., formed together by their first sidewall 226a, third sidewall 226c and fourth sidewall 226d.

In some implementations, as illustrated in FIG. 2A, the end portion 206-1a of the plurality of first curved portions 206 of the first segment 202 includes a first curved surface 205a in contact with the stack 105. The second portion 206-1b of the plurality of first curved portions 206 of the first segment 202 includes a second curved surface 205b in contact with the stack 105. The first curved surface 205a and the second curved surface 205b can be on the third sidewall 226c of the first segment 202. In some implementations, an arc length of the first curved surface 205a in a plane (e.g., X-Y plane) is greater than an arc length of the second curved surface 205b in the plane. The arc length can be the distance measured along each curved surface along x direction, which can be a linear length of the curved surface rather than the straight-line distance between its endpoints. For example, as shown in FIG. 2A, the arc length of the first curved surface 205a can refer to the arc length of the dotted line, while the arc length of the second curved surface 205b can refer to the arc length of the dot-dashed line.

In some implementations, a distance 207 between the end portion 222-1a of the plurality of second curved portions 222 and the end portion 206-1a of the plurality of first curved portions 206 of the first segment 202 is greater than a pitch 209 of the plurality of the first curved portions 206 of the first segment 202. In some implementations, the distance 207 between the end portion 222-1a of the isolation structure 220 and the end portion 206-1a of the first segment 202 is greater than the pitch 209 of the first curved portions 206 of the first segment 202 by at least 5%, at least 10%, at least 20%, at least 30%, at least 40% or at least 50%.

In some implementations, the pitch 209 of the plurality of the first curved portions 206 of the first segment 202 is a distance between centroids 232, 234 of two adjacent first curved portions 206. In some implementations, the distance 207 between the end portion 222-1a of the plurality of second curved portions 222 and the end portion 206-1a of the plurality of first curved portions 206 of the first segment 202 is a distance between a centroid 236 of the end portion 222-1a of the plurality of second curved portions 222 and a centroid 234 of the end portion 206-1a of the plurality of first curved portions 206 of the first segment 202. In other words, the pitch 209 and the distance 207 can refer to the inter-center distance between two corresponding curved portions.

In some examples, the centroid can be a geometric center. The centroid can be the mathematical average of all points in the shape and can be considered the center for irregular, concave or convex shapes. The centroid can also be at a point where the distances to all surface points of a corresponding curved surface are equal. For example, the centroid 232 can be located at a point where the distances to all surface points of the second curved surface 205b is equal or substantially equal. In another example, the centroid 236 of the end portion 222-1a of the isolation structure 220 can be located at a point where the distances to all surface points of the curved surface 227 (e.g., the curved surface on the third sidewall 224c) is equal or substantially equal.

In some implementations, a pitch 211 of the plurality of second curved portions 222 is greater than the pitch 209 of the plurality of the first curved portions 206 of the first segment 202. The pitch 211 of the plurality of second curved portions 222 can be the inter-center distance. In some implementations, the pitch 211 of the plurality of second curved portions 222 is equal to the pitch 209 of the plurality of the first curved portions 206 of the first segment 202. In some implementations, the pitch 209 of the plurality of the first curved portions 206 of the first segment 202 is equal to a pitch 213 of the plurality of the first curved portions 206 of the second segment 204. The pitch 213 of the plurality of first curved portions 206 of the second segment 204 can also be the inter-center distance.

As noted above in reference to FIG. 1, the semiconductor device 100 includes a plurality of channel structures (e.g., the active channel structures 108 and dummy channel structures 110) extending along Z direction. In some implementations, as illustrated in FIG. 2A, a part of the stack 105 is between the isolation structure 220 and the plurality of channel structures along Y direction. For example, the isolation structure 220 can be between two rows of dummy channel structures 110 along Y direction, and a part of the stack 105 can be between the isolation structure 220 and each row of dummy channel structures 110 along Y direction.

Now referring to FIG. 2B, in some implementations, a bottom of the isolation structure 220 includes one or more protrusions 242 extending outward along Z direction and being arranged in the line along X direction. The bottom of the isolation structure can refer to the part of the isolation structure that is close to the substrate 250 of the semiconductor device 200. As described below with reference to FIGS. 3A-1 through 3G-3, the protrusions 242 can be result from the formation of gate line slit holes 310 that extend at least partially into the substrate 250 of the semiconductor device 200.

Although not shown, it is to be understood that the isolation structure 220 can have no protrusions 242 at the bottom. In some implementations, a substrate (e.g., substrate 250) of the semiconductor device (e.g., the semiconductor device 200) is polished or thinned. The substrate 250 and a polysilicon layer 221 in the semiconductor device 200 can be removed. A part of each channel structure (e.g., channel structures 108 in FIG. 1) that was in the substrate 250 can be removed. For example, a part of the channel structure 108’s memory film that includes the ONO dielectrics (silicon Oxide-silicon Nitride-silicon Oxide) can be removed to expose a channel layer (e.g., doped polysilicon). A part of the gate line slit structure 210 that was in the substrate 250 also can be removed to expose a material of the gate line slit structure. A semiconductor layer (not shown) can be formed to connect the gate line slit structure 210 and the channel structures 108. In some implementations, the semiconductor layer can include any suitable semiconductor material (e.g., polysilicon) and can function as an array common source of memory strings (e.g., channel structures 108) of the semiconductor device 200. During the substrate removal or thinning process (e.g., by a chemical mechanical polishing (CMP) process), the protrusions 242 that extend into the substrate 250 of the semiconductor device 200 may be removed. Therefore, in some implementations, the isolation structure 220 has a substantially flat bottom surface without protrusions.

In some implementations, the first segment 202 is in an array region 102, the second segment 204 and the isolation structure 220 are in a connection region 104 adjacent to the array region 102 along X direction. For example, the first segment 202 can be the segment 114a in FIG. 1, while the second segment 204 can be the segment 114b in FIG. 1. The isolation structure 220 can be the isolation structure 106a in FIG. 1.

In some implementations, the first segment 202, the second segment 204, and the isolation structure 220 are in a connection region 104. For example, the first segment 202 can be the segment 114c in FIG. 1, while the second segment 204 can be the segment 114d in FIG. 1. The isolation structure 220 can be the isolation structure 106b in FIG. 1.

In some implementations, the first segment 202, the second segment 204, and the isolation structure 220 are in an array region 102.

FIGS. 3A-1 through 3G-3 illustrate plan views and cross-sectional views of a semiconductor device 300 at various stages of a manufacture process. For each process stage, three views are illustrated: a plan view, a cross-section view in Y-Z plane and a cross-section view in X-Z plane. For example, FIG. 3A-1, FIG. 3A-2 and FIG. 3A-3 can all illustrate a same process stage, with FIG. 3A-1 being the plan view, FIG. 3A-2 being the cross-sectional view in Y-Z plane, and FIG. 3A-3 being the cross-sectional view in X-Z plane. FIG. 3A-1 is a plan view along axis A-A’ of FIG. 3A-3. The same plan view is arranged in FIGS. 3B-1, 3C-1, 3D-1, 3E-1, 3F-1 and 3G-1 as well. For ease of description, reference will be made to all three views when describing each process stage.

Referring to FIGS. 3A-1 through 3A-3, a semiconductor structure (e.g., an initial structure of the semiconductor device 300) can be provided, which include a stack of sacrificial layers 142 and insulating layers 138 alternating with each other along a first direction (e.g., Z direction). The insulating layers 138 can be the insulating layers 138 of FIG. 1. In some implementations, the sacrificial layers 142 can include a dielectric material different from the dielectric material of the insulating layers 138. For example, the insulating layers 138 can include silicon oxide, and the sacrificial layers 142 can include silicon nitride. The sacrificial layers 142 can be replaced with the conductive layers 136 at later stages of the process, as described in further detail below in reference to FIGS. 3G-1 through 3G-3. The stack of sacrificial layers 142 and the insulating layers 138 can be referred to as an initial stack 302 in the present disclosure.

Gate line slit holes 310 can be formed extending through the initial stack 302 along Z direction. The gate line slit holes 310 can extend at least partially into a substrate 350 of the semiconductor device 300. In some implementations, the gate line slit holes 310 are formed together with channel holes 303 at the same process steps (e.g., using a same photolithography mask and/or a same etching process). The channel holes 303 can be used to form active channel structures (e.g., channel structures 108 of FIG. 1) and/or dummy channel structures (e.g., dummy channel structures 110 of FIG. 1). In some implementations, the gate line slit holes 310 have the same size (e.g., shape, diameter, width, and/or depth along X, Y, or Z direction) as the channel holes 303.

The gate line slit holes 310 can be arranged in a line along X direction, as illustrated in FIG. 3A-1. The gate line slit holes 310 can include a first group 304 of gate line slit holes 310, a second group 306 of gate line slit holes 310 and a third group 308 of gate line slit holes 310. The first group 304 of gate line slit holes 310 is between the second group 306 of gate line slit holes 310 and the third group 308 of gate line slit holes 310 along x direction. In some implementations, a cross-section of a gate line slit hole 310 has a circular or substantially circular shape in X-Y plane, as shown in FIG. 3A-1.

In some implementations, the second group 306 of gate line slit holes 310 have equal distance (e.g., pitch) between any two neighboring gate line slit holes 310 within the second group 306. In some implementations, a pitch 305 of the second group 306 of gate line slit holes 310 is the same as a pitch 311 of the third group 308 of gate line slit holes 310. In some implementations, a pitch 309 of the first group 304 of the gate line slit holes 310 (e.g., a distance between any two neighboring gate line slit holes 310 within the first group 304) is the same as the pitch 305 of the second group 306 of gate line slit holes 310. In some implementations, the pitch 309 of the first group 304 of gate line slit holes 310 is different from (e.g., greater than) the pitch 305 of the second group 306 of gate line slit holes 310. The distance and pitch can refer to the inter-center distance between corresponding gate line slit holes 310. The center of each gate line slit hole 310 may be defined as the center of its circular cross-section or a substantially circular cross-section in X-Y plane.

In some implementations, as illustrated in FIG. 3A-1, an end hole 304a of the first group 304 of gate line slit holes 310 is adjacent to an end hole 306a of the second group 306 of gate line slit holes 310. A distance 307 between the end hole 304a of the first group 304 of gate line slit holes 310 and the end hole 306a of the second group 306 of gate line slit holes 310 can be greater than the pitch 305 of the second group 306 of gate line slit holes 310. In some implementations, the distance 307 is greater than the pitch 305 by at least 5%, at least 10%, at least 20%, at least 30%, at least 40% or at least 50%.

In some implementations, the gate line slit holes 310 are filled with a first filler 312. In some implementations, the first filler 312 includes at least one of carbon or polysilicon. The first filler 312 can be deposited using one or more thin film deposition techniques, including, but not limited to, chemical vapor deposition (CVD), physical vapor deposition (PVD), plasma enhanced chemical vapor deposition (PECVD) atomic layer deposition (ALD), sputtering, or any combination thereof.

In some implementations, a first interlayer dielectric (ILD) 318 is formed above the gate line slit holes 310, as illustrated in FIG. 3A-3. The first ILD 318 can include dielectric materials including, but not limited to, silicon oxide, silicon nitride, silicon oxynitride, or any combination thereof.

Referring now to FIGS. 3B-1 through FIGS. 3B-3, FIG. 3B-2 is a cross-sectional view along axis B-B’ of FIG. 3B-1. The same cross-sectional view is arranged in FIG. 3C-2 as well. A first opening 316 can be formed extending through the first ILD 318 and exposing the second group 306 and the third group 308 of gate line slit holes 310. The first group 304 of the gate line slit holes 310 can still be covered by the first ILD 318 at this process stage, as illustrated in FIG. 3B-3. The first opening 316 can be formed by a plurality of processes including, but not limited to, photolithography, dry/wet etch, and any other suitable processes.

As illustrated in FIGS. 3C-1 through 3C-3, the first filler 312 in the second group 306 of gate line slit holes 310 and the third group 308 of gate line slit holes 310 can be removed. A first segment 320A of a gate line slit trench 320 and a second segment 320B of the gate line slit trench 320 can be formed by expanding the second group 306 of gate line slit holes 310 and the third group 308 of gate line slit holes 310, respectively. The expanded gate line slit holes 310’ can have a greater size along lateral directions (e.g., X direction and Y direction) compared to the gate line slit holes 310 before expansion. The expanded gate line slit holes 310’ from the second group 306 are connected with each other along X direction, and similarly the expanded gate line slit holes 310’ from the third group 308 are also connected with each other along X direction. For ease of description, the expanded gate line slit holes 310’ from the second group 306 of gate line slit holes 310 can be referred to as the expanded gate line slit holes 306’, while the expanded gate line slit holes 310’ from the third group 308 of gate line slit holes 310 can be referred to as the expanded gate line slit holes 308’ in the present disclosure.

In some implementations, expanding the gate line slit holes 310 involves one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof. During this expanding process, the first group 304 of gate line slit holes 310 can be protected by the first ILD 318.

In some implementations, as illustrated in FIG. 3C-3, the first segment 320A of the gate line slit trench 320 and the second segment 320B of the gate line slit trench 320 are separated, by a part of the initial stack 302, from the first group 304 of gate line slit holes 310 that is filled with the first filler 312. Therefore, the first filler 312 inside the first group 304 of gate line slit holes 310 are not exposed in the first segment 320A of the gate line slit trench 320 or the second segment 320B of the gate line slit trench 320 at this process stage due to increased distance (e.g., the distance 307 of FIG. 3A-1) between the first and second group of gate line slit holes 310. This increase distance can reduce the risk of the first filler 312 inside the first group 304 of gate line slit holes 310 being eroded or oxidized by chemicals used in the formation of the gate line slit structures. Therefore, without the concern of erosion, a more cost-effective sacrificial material (e.g., carbon) can be used as the first filler 312 for the first group 304 of gate line slit holes 310, thereby lowering manufacture costs.

Referring now to FIGS. 3D-1 through 3D-3 , FIG. 3D-2 is a cross-sectional view along axis C-C’ of FIG. 3D-1. The same cross-sectional view is arranged in FIG. 3E-2, 3F-2 and 3G-2 as well. The second filler 322 can be deposited in the gate line slit trench 320. The second filler 322 can have a material same as or different from that of the first filler 312. In some implementations, the second filler 322 includes at least one of polysilicon or carbon.

In some implementations, a second ILD 319 is formed on the first ILD 318. The second ILD 319 and the first ILD 318 can have the same material. Therefore, the two ILDs may not be distinguishable from each other in a real device. For ease of description, either the first ILD 318, the second ILD 319, or the stack of two ILDs can be referred to as a ILD layer 321 in the present disclosure. A second opening 326 can be formed extending through the ILD layer 321 to expose at least a part of the first filler 312 in each gate line slit hole 310 of the first group 304 of gate line slit holes 310. As illustrated in FIG. 3D-3, as the first filler 312 in the first group 304 of gate line slit holes 310 are spaced further away from the second filler 322 due to increased distance (e.g., the distance 307 of FIG. 3A-1), the process window for forming the second opening 326 can be enlarged, allowing the second opening 326 to have more room to expand laterally towards the second fillers 322. Additionally, the risk of eroding the second filler 322 through chemicals introduced through the second opening 326 can also be reduced.

As illustrated in FIGS. 3E-1 through 3E-3 , the first filler 312 can be removed from the first group 304 of gate line slit holes 310 through the second opening 326. The first group 304 of gate line slit holes 310 can be expanded such that the expanded gate line slit holes 310’ from the first group 304 of gate line slit holes 310 are connected with each other along the second direction. Similar to the process described above for expanding the second and third group 306, 308 of gate line slit holes 310, expanding the first group 304 of gate line slit holes 310 can involve one or more dry etching and/or wet etching techniques. The expanded first group 304’ of gate line slit holes 310 can form an isolation trench 328.

In some implementations, as illustrated in FIG. 3E-1, the gate line slit trench 320 (filled with the second filler 322) and the isolation trench 328 are connected (e.g., in contact with each other). As noted above, the gate line slit structure (e.g., gate line slit structure 210) and the isolation structure 220 can be used to separate neighboring memory blocks. With the gate line slit trench 320 and the isolation trench 328 being connected, the electrical communication (or leakage) between adjacent memory blocks (e.g., memory blocks 332A, 332B in FIG. 3E-1) can be reduced or eliminated.

As illustrated in FIGS. 3F-1 through 3F-3 , an isolation structure 330 can be formed by filling a dielectric material into the isolation trench 328. The isolation trench 328 can be formed after depositing the second filler 322 in the gate line slit trench 320 (e.g., as described above in reference to FIGS. 3C-1 through 3D-3 ). The dielectric material can include, but not limited to, silicon oxide, silicon nitride, silicon oxynitride, or any combination thereof. The dielectric material can be deposited using one or more thin film deposition techniques, including, but not limited to, chemical vapor deposition (CVD), physical vapor deposition (PVD), plasma enhanced chemical vapor deposition (PECVD) atomic layer deposition (ALD), sputtering, or any combination thereof.

In some implementations, the first segment 320A of the gate line slit trench 320 is in the array region 102 of the semiconductor device 300, and the isolation structure 330 and the second segment 320B of the gate line slit trench 320 are in the connection region 104 of the semiconductor device 300. For example, the first segment 320A of the gate line slit trench 320 can correspond to the segment 114a in FIG. 1, while the second segment 320B of the gate line slit trench 320 can correspond to the segment 114b in FIG. 1. The isolation structure 330 can be the isolation structure 106a in FIG. 1.

As illustrated in FIGS. 3G-1 through 3G-3, the sacrificial layers 142 can be replaced with the conducive layers 136 to form the stack 105. This replacement process can involve multiple process steps as described below. These process steps may not be illustrated in FIGS. 3G-1 through 3G-3. It is to be noted that the example process steps and the example order of these process steps described below are not intended to be construed in a limiting sense. For example, although the process steps described below involve forming the space openings between insulating layers 138 in the connection region 104 first, the space openings in the array region 102 can be formed first instead in some other examples.

In some implementations, the sacrificial layers 142 in a connection region 104 of the semiconductor structure are removed. This removal process can involve (i) removing the second filler 322 in the second segment 320B of the gate line slit trench 320 and (ii) removing, by introducing an etchant (e.g., a wet etchant) through the second segment 320B of the gate line slit trench 320, the sacrificial layers 142 in the connection region 104 to form second opening space. Removing the second filler 322 and removing the sacrificial layers 142 can involve one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof. In some implementations, after removing the sacrificial layers 142, the second segment 320B of the gate line slit trench 320 and the second opening space are at least partially filled with a third filler. The third filler can have the same material as the first filler 312 or the second filler 322. For example, the third filler can include at least one of a dielectric material, polysilicon or carbon.

In some implementations, the sacrificial layers 142 in an array region 102 of the semiconductor structure are subsequently removed. This removal process can involve removing the second filler 322 in the first segment 320A of the gate line slit trench 320 and removing, by introducing the etchant through the first segment 320A of the gate line slit trench 320, the sacrificial layers 142 in the array region 102 to form first opening space. One or more etching techniques can be used as described above. In some implementations, the removal of sacrificial layers 142 in the array region 102 involves a longer etch time that the removal of sacrificial layers 142 in the connection region 104.

Next, the third filler in the connection region 104 can be removed. Therefore, both the first segment 320A and the second segment 320B of the gate line slit trench 320 can be exposed without any filler inside.

In some implementations, conductive layers 136 are deposited into the first space openings and the second space openings between the insulating layers 138 in both the connection region 104 and the array region 102. The conductive layers 136 can be deposited into the first opening space and the second opening space through the first segment 320A of the gate line slit trench 320 and the second segment 320B of the gate line slit trench 320, respectively. At this process stage, the stack 345 of insulating layers 138 and conductive layers 136 can be formed. The stack 345 can be the stack 105 of FIG. 1.

Finally, in some implementations, a spacer layer 344 is deposited in the gate line slit trench 320 (including the first segment 320A and the second segment 320B), followed by a deposition of a final filler 342 to fill the gate line slit trench 320. The final filler 342 can include polysilicon. The spacer layer 344 and the final filler 342 can be deposited using one or more thin film deposition processes including, but not limited to, CVD, PVD, ALD, MOCVD, MBE, sputtering, or any combination thereof.

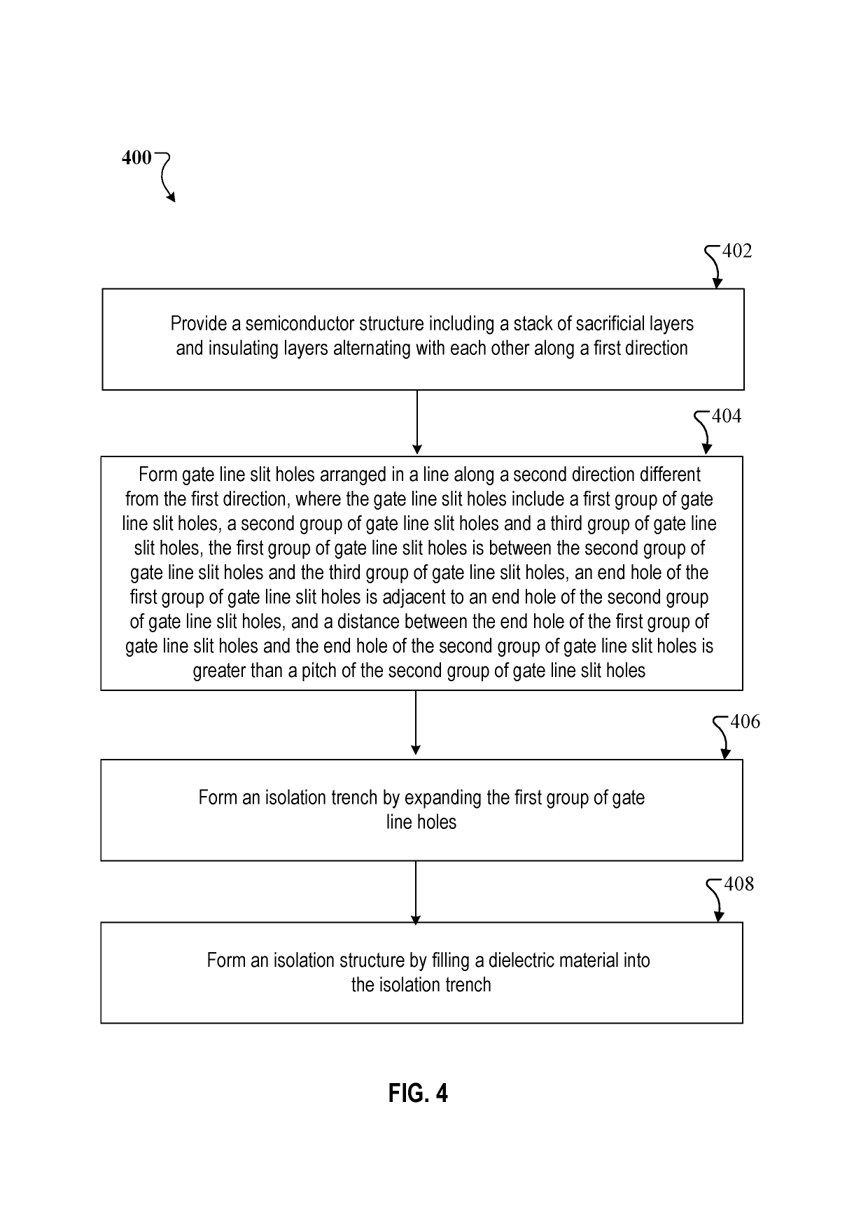

FIG. 4 is a flowchart of a process 400 of an example method to form a semiconductor device. The semiconductor device can be, e.g., the 3D semiconductor device 100 of FIG. 1, a part of the 3D semiconductor device (e.g., semiconductor device 200 of FIGS. 2A-2B), or a structure at an intermediate fabrication process of the 3D semiconductor device 300 of FIGS. 3A-1 through 3G-3.

At step 402, a semiconductor structure is formed including a stack of sacrificial layers and insulating layers alternating with each other along a first direction. The semiconductor structure can be a part of the semiconductor device and include a substrate (e.g., substrate 250 of FIG. 2B, or substrate 350 of FIGS. 3A-1 through 3G-3). The stack can be, e.g., the initial stack 302 of FIGS. 3A-1 through 3F-3. The sacrificial layers can be, e.g., sacrificial layers 142 of FIGS. 3A-1 through 3F-3. The insulating layers can be, e.g., insulating layers 138 of FIGS. 1 through 3G-3.

At step 404, gate line slit holes are formed. Gate line slit holes are arranged in a line along a second direction different from the first direction, where the gate line slit holes include a first group of gate line slit holes, a second group of gate line slit holes and a third group of gate line slit holes, the first group of gate line slit holes is between the second group of gate line slit holes and the third group of gate line slit holes, an end hole of the first group of gate line slit holes is adjacent to an end hole of the second group of gate line slit holes, and a distance between the end hole of the first group of gate line slit holes and the end hole of the second group of gate line slit holes is greater than a pitch of the second group of gate line slit holes. Gate line slit holes can be, e.g., the gate line slit holes 310 of FIGS. 3A-1 through 3D-3. The first group of gate line slit holes can be, e.g., the first group 304 of gate line slit holes 310 of FIGS. 3A-1 through 3D-3. The second group of gate line slit holes can be, e.g., the second group 306 of gate line slit holes 310 of FIGS. 3A-1 through 3B-3. The third group of gate line slit holes can be, e.g., the third group 308 of gate line slit holes 310 of FIGS. 3A-1 through 3B-3. The end hole of the first group of gate line slit holes can be, e.g., end hole 304a of the first group 304 of gate line slit holes 310 in FIG. 3A-1. The end hole of the second group of gate line slit holes can be, e.g., the end hole 306a of the second group 306 of gate line slit holes 310 in FIG. 3A-1. The distance between the end hole of the first group of gate line slit holes and the end hole of the second group of gate line slit holes can be, e.g., the distance 307 of FIG. 3A-1. The pitch of the second group of gate line slit holes can be, e.g., the pitch 305 of FIG. 3A-1.

At step 406, an isolation trench is formed by expanding the first group of gate line slit holes. The isolation trench can be, e.g., the isolation trench 328 of FIGS. 3E-1 through 3E-3.

At step 408, an isolation structure is formed by filling a dielectric material into the isolation trench. The isolation structure can be, e.g., the isolation structure 106 of FIG. 1, the isolation structure 220 of FIGS. 2A and 2B, or the isolation structure 330 of FIGS. 3F-1 through 3G-3.

In some implementations, a pitch of the first group of gate line slit holes is greater than the pitch of the second group of gate line slit holes. The pitch of the first group of gate line slit holes can be, e.g., the pitch 309 of FIG. 3A-1.

In some implementations, a pitch of the second group of gate line slit holes is equal to a pitch of the third group of gate line slit holes. The pitch of the third group of gate line slit holes can be, e.g., the pitch 311 of FIG. 3A-1.

In some implementations, the isolation trench includes expanded gate line slit holes formed from the first group of gate line slit holes, and the expanded gate line slit holes from the first group of gate line slit holes are connected with each other along the second direction. The expanded gate line slit holes from the first group of gate line slit holes can be, e.g., the expanded first group 304’ of FIGS. 3E-1 through 3E-3.

In some implementations, the method includes filling the gate line slit holes with a first filler; removing the first filler in the second group of gate line slit holes and the third group of gate line slit holes; forming a first segment of a gate line slit trench and a second segment of the gate line slit trench by expanding the second group of gate line slit holes and the third group of gate line slit holes, respectively. The expanded gate line slit holes from the second group of gate line slit holes are connected with each other along the second direction, and the expanded gate line slit holes from the third group of gate line slit holes are connected with each other along the second direction; and depositing a second filler in the gate line slit trench. The first filler can be, e.g., the first filler 312 of FIGS. 3A-1 through 3D-3. The first segment of the gate line slit trench can be, e.g., the first segment 320A of the gate line slit trench 320 of FIGS. 3C-1 and 3C-3. The second segment of the gate line slit trench can be, e.g., the second segment 320B of the gate line slit trench 320 of FIGS. 3C-1 and 3C-3. The expanded gate line slit holes from the second group of gate line slit holes can be, e.g., the expanded gate line slit holes 306’ of FIGS. 3C-1 through 3C-3. The expanded gate line slit holes from the third group of gate line slit holes can be, e.g., the expanded gate line slit holes 308’ of FIGS. 3C-1 and 3C-3. The second filler can be, e.g., the second filler 322 of FIGS. 3D-1, 3D-3, 3E-1, 3E-3, 3F-1 and 3F-3.

In some implementations, the first segment of the gate line slit trench and the second segment of the gate line slit trench are separated from the first group of gate line slit holes that is filled with the first filler by a part of the stack, as described above in reference to FIG. 3C-3.

In some implementations, the gate line slit trench and the isolation trench are connected, as described above in reference to FIG. 3E-3.

In some implementations, the isolation trench is formed after depositing the second filler in the gate line slit trench, as described above in reference to FIGS. 3A-1 through 3F-3.

In some implementations, forming the isolation trench includes forming a dielectric layer on the first group of gate line slit holes that are filled with the first filler; forming an opening extending through the dielectric layer to expose at least a part of the first filler in each gate line slit hole of the first group of gate line slit holes; and removing the first filler in the first group of gate line slit holes. The dielectric layer can be, e.g., the first ILD 318 of FIGS. 3A-1 through 3C-3, the second ILD 319 of FIGS. 3D-1 through 3G-3, or the ILD layer 321 of FIGS. 3D-1 through 3G-3. The opening can be, e.g., the second opening 326 of FIGS. 3D-2 and 3D-3.

In some implementations, the method includes removing the sacrificial layers in a connection region of the semiconductor structure; removing the sacrificial layers in an array region of the semiconductor structure, the array region is adjacent to the connection region along the second direction; and forming conductive layers 136 between the insulating layers in both the connection region and the array region. The connection region can be, e.g., the connection region 104 of FIG. 1. The array region can be, e.g., the array region 102 of FIG. 1. The conductive layers 136 can be, e.g., the conductive layers 136 of FIGS. 1 and 3G-2.

In some implementations, the method includes removing the second filler in the second segment of the gate line slit trench; removing, by introducing an etchant through the second segment of the gate line slit trench, the sacrificial layers in the connection region to form second opening space; filling the second segment of the gate line slit trench and the second opening space with a third filler; removing the second filler in the first segment of the gate line slit trench; removing, by introducing the etchant through the first segment of the gate line slit trench, the sacrificial layers in the array region to form first opening space; removing the third filler in the connection region; and depositing at least a conductive material into the first opening space and the second opening space through at least one of the first segment of the gate line slit trench or the second segment of the gate line slit trench, as described above in reference to FIGS. 3G-1 through 3G-3.

In some implementations, the method includes depositing a spacer layer in the gate line slit trench; and depositing a final filler in the gate line slit trench. The spacer layer can be, e.g., the spacer layer 344 of FIGS. 3G-1 and 3G-3. The final filler can be, e.g., the final filler 340 of FIG. 3G-3.

In some implementations, the first segment of the gate line slit trench is in the array region of the semiconductor structure, and the isolation structure and the second segment of the gate line slit trench are in the connection region of the semiconductor structure. The first segment can correspond to the segment 114a in FIG. 1, while the second segment can correspond to the segment 114b in FIG. 1. The isolation structure can be the isolation structure 106a in FIG. 1.

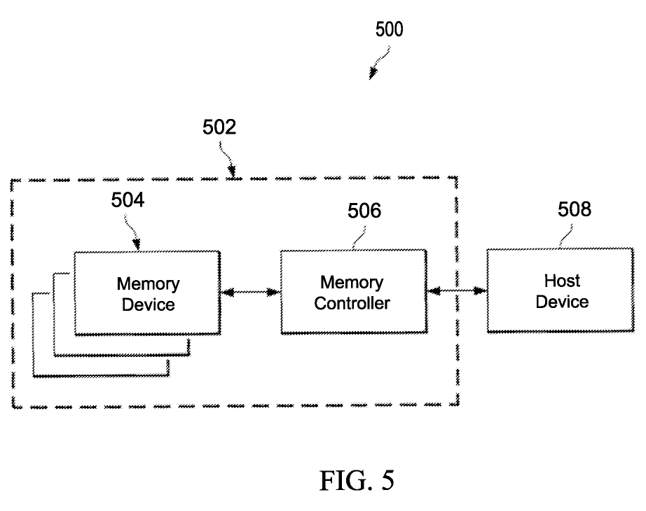

FIG. 5 illustrates a block diagram of a system 500 having one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 5, the system 500 can include a host device 508 and a memory system 502 having one or more 3D memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more 3D memory devices 504.

A 3D memory device 504 can be any 3D memory device disclosed herein, such as the 3D semiconductor device 100 of FIG. 1, or a part of the 3D semiconductor device 200 of FIGS. 2A-2B, or a structure at an intermediate fabrication process of the 3D semiconductor device 300 of FIGS. 3A-1 through 3G-3.

In some implementations, a 3D memory device 504 includes a NAND Flash memory. Memory controller 506 (a.k.a., a controller circuit) is coupled to 3D memory device 504 and host device 508. Consistent with implementations of the present disclosure, 3D memory device 504 can include a plurality of conductive interconnections through a cover layer that are in contact with conductive pads in a conductive pad layer, and memory controller 506 can be coupled to 3D memory device 504 through at least one of the plurality of conductive interconnections. Memory controller 506 is configured to control 3D memory device 504. For example, memory controller 506 may be configured to operate a plurality of channel structures via word lines. Memory controller 506 can manage data stored in 3D memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of 3D memory device 504, such as read, erase, and program (or write) operations. Memory controller 506 can also be configured to manage various functions with respect to the data stored or to be stored in 3D memory device 504 including, but not limited to bad-block management, garbage collection, logical-to-physical address conversion, wear leveling, etc. In some implementations, memory controller 506 is further configured to process error correction codes (ECCs) with respect to the data read from or written to 3D memory device 504. Any other suitable functions may be performed by memory controller 506 as well, for example, formatting 3D memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more 3D memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single 3D memory device 504 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature’s relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+-.10%, .+-.20%, or .+-.30% of the value).

As used in this disclosure, the term “substantially” or “substantial” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

As used herein, the term “surrounded by” refers to at least partially surrounded by. For example, A is surrounded by B can refer to that A is at least partially surrounded by B.

As used herein, the term “and/or” as used herein refers to and encompasses any and all possible combinations of one or more of the associated listed terms. For example, the term “A and/or B” means that either option A, option B, or both options A and B are possible, where A and B may be singular or plural.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a stack of conductive layers and insulating layers alternating with each other along a first direction;
a gate line slit structure extending in the stack and comprising at least a first segment and a second segment each having a plurality of first curved portions arranged in a line along a second direction different from the first direction, wherein the plurality of first curved portions of the first segment comprises an end portion and a second portion in contact with the end portion; and
an isolation structure extending in the stack and separating the first segment from the second segment in the line along the second direction,
wherein the isolation structure comprises a plurality of second curved portions arranged in the line along the second direction, and an end portion of the plurality of second curved portions is in contact with the end portion of the plurality of first curved portions of the first segment along the second direction, and
wherein the end portion of the plurality of first curved portions of the first segment comprises a first curved surface in contact with the stack, the second portion of the plurality of first curved portions of the first segment comprises a second curved surface in contact with the stack, and an arc length of the first curved surface in a plane perpendicular to the first direction is greater than an arc length of the second curved surface in the plane.

2. The semiconductor device of claim 1, wherein a distance between the end portion of the plurality of second curved portions and the end portion of the plurality of first curved portions of the first segment is greater than a pitch of the plurality of the first curved portions of the first segment.

3. The semiconductor device of claim 2, wherein a pitch of the plurality of second curved portions is greater than the pitch of the plurality of the first curved portions of the first segment.

4. The semiconductor device of claim 2, wherein the pitch of the plurality of the first curved portions of the first segment is a distance between centroids of two adjacent first curved portions, and the distance between the end portion of the plurality of second curved portions and the end portion of the plurality of first curved portions of the first segment is a distance between a centroid of the end portion of the plurality of second curved portions and a centroid of the end portion of the plurality of first curved portions of the first segment.

5. The semiconductor device of claim 1, wherein the end portion of the plurality of second curved portions comprises a concave surface, and the end portion of the plurality of first curved portions of the first segment comprises a convex surface in contact with the concave surface.

6. The semiconductor device of claim 1, wherein the isolation structure comprises a first sidewall in contact with the first segment and a second sidewall in contact with the second segment, the first sidewall and the second sidewall each has a concave surface extending inwardly along the second direction, and
wherein the isolation structure further comprises a third sidewall and a fourth sidewall both in contact with the stack along a third direction different from the first direction and the second direction, and the third sidewall and the fourth sidewall each comprise a series of curved surfaces including the first curved surface and the second curved surface.

7. The semiconductor device of claim 1, comprising:
a plurality of channel structures extending along the first direction,
wherein a part of the stack is between the isolation structure and the plurality of channel structures along a third direction different from the first direction and the second direction.

8. The semiconductor device of claim 1, wherein the first segment is in an array region, the second segment and the isolation structure are in a connection region adjacent to the array region along the second direction.

9. The semiconductor device of claim 1, wherein the first segment, the second segment, and the isolation structure are in an array region.

10. A method, comprising:
providing a semiconductor structure comprising a stack of sacrificial layers and insulating layers alternating with each other along a first direction;
forming gate line slit holes arranged in a line along a second direction different from the first direction, wherein the gate line slit holes comprise a first group of gate line slit holes, a second group of gate line slit holes and a third group of gate line slit holes, the first group of gate line slit holes is between the second group of gate line slit holes and the third group of gate line slit holes, an end hole of the first group of gate line slit holes is adjacent to an end hole of the second group of gate line slit holes, and a distance between the end hole of the first group of gate line slit holes and the end hole of the second group of gate line slit holes is greater than a pitch of the second group of gate line slit holes;
forming an isolation trench by expanding the first group of gate line slit holes; and
forming an isolation structure by filling a dielectric material into the isolation trench.

11. The method of claim 10, wherein a pitch of the first group of gate line slit holes is greater than the pitch of the second group of gate line slit holes.

12. The method of claim 10, wherein the isolation trench comprises expanded gate line slit holes formed from the first group of gate line slit holes, and the expanded gate line slit holes from the first group of gate line slit holes are connected with each other along the second direction.

13. The method of claim 10, comprising:
filling the gate line slit holes with a first filler;
removing the first filler in the second group of gate line slit holes and the third group of gate line slit holes;
forming a first segment of a gate line slit trench and a second segment of the gate line slit trench by expanding the second group of gate line slit holes and the third group of gate line slit holes, respectively, wherein the expanded gate line slit holes from the second group of gate line slit holes are connected with each other along the second direction, and the expanded gate line slit holes from the third group of gate line slit holes are connected with each other along the second direction; and
depositing a second filler in the gate line slit trench.

14. The method of claim 13, wherein the first segment of the gate line slit trench and the second segment of the gate line slit trench are separated from the first group of gate line slit holes that is filled with the first filler by a part of the stack.

15. The method of claim 13, wherein the gate line slit trench and the isolation trench are connected.

16. The method of claim 13, wherein the isolation trench is formed after depositing the second filler in the gate line slit trench.

17. The method of claim 13, wherein forming the isolation trench comprises:
forming a dielectric layer on the first group of gate line slit holes that are filled with the first filler;
forming an opening extending through the dielectric layer to expose at least a part of the first filler in each gate line slit hole of the first group of gate line slit holes; and
removing the first filler in the first group of gate line slit holes.

18. The method of claim 13, comprising:
removing the sacrificial layers in a connection region of the semiconductor structure;
removing the sacrificial layers in an array region of the semiconductor structure, the array region being adjacent to the connection region along the second direction; and
forming conductive layers between the insulating layers in both the connection region and the array region.

19. The method of claim 10, wherein a pitch of the second group of gate line slit holes is equal to a pitch of the third group of gate line slit holes.

20. A memory system, comprising:
a memory device; and
a memory controller coupled to the memory device and configured to control the memory device,
wherein the memory device comprises:
a stack of conductive layers and insulating layers alternating with each other along a first direction;
a gate line slit structure extending in the stack and comprising at least a first segment and a second segment each having a plurality of first curved portions arranged in a line along a second direction different from the first direction, wherein the plurality of first curved portions of the first segment comprises an end portion and a second portion in contact with the end portion; and
an isolation structure extending in the stack and separating the first segment from the second segment in the line along the second direction,
wherein the isolation structure comprises a plurality of second curved portions arranged in the line along the second direction, and an end portion of the plurality of second curved portions is in contact with the end portion of the plurality of first curved portions of the first segment along the second direction, and
wherein the end portion of the plurality of first curved portions of the first segment comprises a first curved surface in contact with the stack, the second portion of the plurality of first curved portions of the first segment comprises a second curved surface in contact with the stack, and an arc length of the first curved surface in a plane perpendicular to the first direction is greater than an arc length of the second curved surface in the plane.
